(19) United States
(12) Patent Application Publication
(10) Pub. No.: US 2008/0213978 A1
(43) Pub. Date: Sep. 4, 2008

(54) Debris management for wafer singulation

(75) Inventors: Kathaleen Henry, Healdsburg, CA (US); Ferdinand Seemann, Livermore, CA (US); Karen Ann Reinhardt, San Jose, CA (US); David Acher Setton, Oakland, CA (US); Stefano Mangano, Menlo Park, CA (US); Adel George Tannous, Santa Clara, CA (US); Khalid Makhamreh, Los Gatos, CA (US)

Correspondence Address: TUE NGUYEN, 496 OLIVE AVE, FREMONT, CA, 94539, US

(73) Assignee: DYNATEX, Santo Rosa, CA (US)

(21) Appl. No.: 11/875,893

(22) Filed: Oct. 20, 2007

Related U.S. Application Data
(60) Provisional application No. 60/904,764, filed on Mar. 3, 2007.

(51) Int. Cl. H01L 21/304; B23K 9/00

(52) U.S. Cl. 438/462; 219/121.67; 257/E21.238

(57) ABSTRACT

The present invention discloses methods and apparatuses for substrate singulation. Embodiments of the present invention comprise cryogenic-assist scribing or cutting mechanism for debris reduction, preferably cryogenic-assist laser scribe or cutting; controlling mechanism for debris flow and redeposition during laser process; and integrated, dry debris removal scribing process with breaking mechanism. An exemplary embodiment comprises an integrated housing for aligning a laser beam with the cryogenic cleaning beam. The integrated housing is preferably made of low thermal conductivity material to provide a high temperature gradient between the low temperature of the cryogenic fluid and the ambient temperature, preventing condensation of the moisture. The entire areas, or the critical areas of the apparatus can also be purged with flowing “dry” inert gases to further reduce the condensation moisture. Reactive gas can be introduced to react with debris, converting into gaseous form for ease of removal.

This application claims priority from U.S. provisional patent application Ser. No. 60/838,478, filed on Oct. 20, 2006, entitled “Debris cleaning for post scribing”; and U.S. provisional patent application Ser. No. 60/904,764, filed on Mar. 3, 2007, entitled “Cryogenic cleaning for substrate singulation”; which are incorporated herein by reference.

### FIELD OF THE INVENTION

The present invention relates generally to the field of semiconductor processing and more particularly to an apparatus and method of cleaning substrates after scribing.

### BACKGROUND

In the manufacture of microelectronic devices, such as integrated circuits, a plurality of such devices are fabricated as individual dies on a single semiconductor wafer. After the completion of the fabrication processes, the devices are tested and the dies are separated, typically by scribing and singulating into individual dies. The individual dies are then packaged, ready for board level integration.

The wafers are typically designed with horizontally and vertically extending “streets” between the dies to facilitate the separation of the individual dies. There are two conventional techniques for the separation of semiconductor wafers into individual dies after fabrication. These are: cutting and scribe and break. The cutting operation is typically a sawing process, using a rotating circular abrasive saw blade. This process is efficient for traditional silicon and III-V substrates, but not working well for new substrate materials such as sapphire due to its inherent hardness and strength. Further, sawing creates debris such as wafer particles and dust, thus requiring additional processes washing and clean up, which might damage fragile device structures. Other methods for cutting wafer into individual dies include a laser beam or a combination of laser beam and saw blade.

In the scribe and break operation, the wafer is scribed along the entire length of the street. The scribe is created either by a diamond scribe tool scratching the wafer surface, or a laser or saw cutting a shallow trench in the surface of the wafer. A wet or dry etch can also be used to create such a trench. A force is then applied to the wafer which stresses the wafer and causes it to break along the scribe lines. In this way the wafer is separated into individual die. This force may be applied via a roller, a dome press, or other pressure technique. Typical breaking mechanisms also apply force to both sides of the semiconductor wafer as part of the breaking procedure. There are many types of semiconductor wafers, some of which would be damaged if force were applied to the top surface of the wafer. To avoid contacting the top surface, vacuum suction can be applied to the backside of the wafer, but the suction is typically not strong enough to withstand the stress caused by the breaking mechanism.

The scribing process, either with diamond scribe, partial saw or laser ablation, produces debris on the wafer. Debris in the form of condensed material from the scribing process deposits on the surface of the substrate and must be removed for optimal device performance. For example, a diamond scribe scatters debris around the wafer surface, and a laser scribing process uses ablation (heat) to vaporize the material to be cut, forming trenches by the evaporation of the wafer material. This vapor is composed of the substrate material and does not form volatile by-products. The vaporized material resolidifies on the substrate surface or re-deposits around the periphery of the cut lines once cooler temperatures are reached. This re-deposited material, debris, may condense in areas that are sensitive and lead to yield loss. For example, the debris could cover the device contacts, or forming ridges of slag which interfere with subsequent testing and bonding of the devices in the wafer.

Prior arts have included the use of a vacuum absorber for absorbing the scattered debris scattered, water cleaning or ultrasonic washing of the scribed wafer. However, these practices do not work well, especially for laser scribe process due to the high temperature fusability of the debris.

### SUMMARY

The present invention discloses methods and apparatuses for substrate singulation. Embodiments of the present invention comprise cryogenic-assist scribing or cutting mechanism for debris reduction, preferably cryogenic-assist laser scribe; controlling mechanism for debris flow and redeposition during laser process; and integrated, dry debris removal scribing process with a breaking mechanism.

One aspect of the present invention provides cryogenic aerosol cleaning for a singulating process, such as scribing, cutting, or sawing process, and preferably laser scribe or cut. In an exemplary embodiment, the present invention provides an in-situ cryogenic cleaning for a laser cutting beam. Besides the cleaning power inherent in cryogenic aerosol cleaning process, the cryoaerosol process can provide an environment management to improve the cleaning power, such as cooling the debris before hitting the surface, thus reducing bonding to the cutting surface, altering potential debris by means of additive or surfactant gas to further reduce adhesion. In addition, solvent or other cryogenic agents can be added to further the cleaning and decontaminating process. Also, the cryoaerosol also allows the management of the temperature of the product which helps to protect sensitive materials from the heat and other physical effects generated by the laser cutting.

In an embodiment, the present invention comprises a laser for performing a laser cut, and a cryogenic aerosol nozzle for cleaning the laser cut. There can be a plurality of cryogenic cleaning nozzles, either arranged in parallel to cover a wider width, in series for increasing cleaning power, or in a matrix for both width and power improvement. The cryogenic cleaning nozzles can either follow the laser beam, be at the same focus point or lead the laser beam to clean the debris generated by the laser cut and pre-condition the environment around the laser and condition the debris generated by the laser ablation and thermal processes. The assembly preferably comprises an integrated housing for aligning the laser beam with the cryogenic beam. The integrated housing comprises at least a passage for the cryogenic fluid, and at least a passage for the laser beam. The passage for the laser beam preferably allows light to pass through, such as a hollow section or transparent material, or lense assembly for guiding or focusing the laser beam. The passage for the cryogenic fluid (liquid, gas, or liquid/gas mixture) preferably allows the cryogenic fluid to pass through, such as an inlet/outlet passage, an adapted section for accommodating a cryogenic delivery assembly, such as a cryogenic delivery line and/or a cryogenic nozzle. The assembly is preferably enclosed in an enclosure having an exhaust to remove contaminants, scattered debris, the generated particles, and the cleaning by-products.

In one aspect, the present invention provides an environmental control to improve the efficiency of the cryogenic cleaning mechanism. In an exemplary, the integrated housing is made of low thermal conductivity material. The low thermal conductivity provides a high temperature gradient between the low temperature of the cryogenic fluid and the ambient temperature, preventing condensation of the moisture, which causes freezing problems. In another exemplary, low humidity gas is purged around the integrated housing, in the vicinity of the cryogenic beam, in the substrate, in the vicinity of the laser beam, in the enclosure, around the apparatus or any combination thereof. This purge prevents secondary condensation problem. In another exemplary, flow dynamic enclosure is provided to carry the particles to the exhaust, preventing redeposition. The exhaust may be assisted by a vortex to enhance debris removal, for example the debris dislodged from the cryogenic blast. The assembly also may include reactive gas directed at the laser-substrate intersection.

In one aspect, the present invention provides a laser control to improve the performance of the laser scribing mechanism. Additional cryogenic nozzles can be supplied in the vicinity of the laser beam. The additional cryogenic nozzles are preferably low power (than the cleaning nozzles) for debris prevention, reduction, and for redeposition control during the laser cut. The supplying of a cryogenic zone surrounding the laser beam can reduce adhesion of melted particles redeposited onto the substrate, plus preventing excess temperature of the substrate.

In one aspect, the present invention provides an ultrasonic or megasonic agitator to improve the performance of the cryogenic cleaning mechanism. The cryogenic fluid can be pulsated by ultrasonic or megasonic agitators on the fluid delivery line before the nozzle. The pulsation of the fluid can be transferred to the ice particles, and thus providing a pulsating action on the cryogenic aerosol cleaning action.

In an embodiment, the present invention provides an integrated system for cryogenic assist laser scribing and mechanical breaking. The cryogenic assisted laser scribing process is a precursor for the die singulating process, such as breaking or complete sawing, to separate the wafer into individual dies. The combination of debris controlled laser scribing followed by breaking on one platform enables the processing of thin wafers (<100 um) that are very brittle. Any kind of transportation between process equipment bears a high risk of material breakage. The present invention further provides optional equipment such as an automation system with X-Y movement and rotation, robotic for moving wafers, scribe station and singulating station for separating the individual dies.

### BRIEF DESCRIPTION OF THE DRAWINGS

FIG. 1 shows a cryogenic cleaning process.

FIG. 2A shows an embodiment of cryogenic cleaning according to the present invention.

FIG. 2B shows an embodiment of cryogenic assisted laser cutting according to the present invention.

FIGS. 3A and 3B show an exemplary configuration for cryogenic assisted laser cutting according to the present invention,

FIG. 4 shows an exemplary system incorporating cryogenic assist laser scribe mechanism.

FIG. 5 shows an exemplary laser assembly.

FIG. 6 shows an exemplary cryogenic assist laser scribing assembly.

FIG. 7 show an exemplary cleaning surface without debris removal, with debris prevention, and with the present invention debris management system.

FIG. 8 shows a street breaking assembly.

FIG. 9 shows a street breaking mechanism.

### DETAILED DESCRIPTION

The present invention discloses methods and apparatuses for substrate singulation. Embodiments of the present invention comprise cryogenic-assist scribing mechanism for debris reduction, preferably cryogenic-assist laser scribe; controlling mechanism for debris flow and redeposition during scribe process; and integrated, dry debris removal scribing process with street-focus breaking mechanism.

In an embodiment, the present invention discloses methods and apparatuses for cleaning a substrate after the formation of debris. An exemplary embodiment is the use of cryogenic aerosol cleaning process for substrate cleaning. In one aspect, the debris formation is from a scribe, cut or saw process, such as a laser scribe or laser cut process.

In an embodiment, the present invention comprises a laser for performing a laser cut, and a cryogenic aerosol nozzle for cleaning the laser cut. One aspect of the present invention provides a cryogenic assisted laser cutting or scribing where a laser cutting beam is accompanied by a cryogenic aerosol spray. The cryogenic aerosol spray can generate e.g. carbon dioxide snow comprising solid aerosol particles and gas, directed onto the surface of the laser cutting. The spray includes discrete, substantially frozen, cleaning particles, which can vaporize after impingement on the cutting surface. The cryogenic aerosol spray can clean the cutting surface in various operating conditions, is versatile and can provide an effective way to remove the generated debris, leaving essentially no residue, being environmentally friendly with safe and nontoxic agents, and can provide flexibility in cleaning intensity. The cryogenic fluid provides cooling of particles to −120C, affects particle adhesion reduction for ease of removal, and provides energy reduction of particles due to cool down, ice/particles collisions and surface modification. The expanding cryoaerosol generates solid particles (e.g. CO₂) of a specified and desired size and energy to effectively clean the debris by rolling, sliding, bouncing debris particles and films of the surface. CO₂ solvent effects may also contribute at the moment of impact of the ice particles and a potential phase change.

Further, besides the cleaning power inherent in cryogenic aerosol cleaning process, the cryogenic aerosol spray can provide an environment management to improve the cleaning power, such as cooling the debris slowing of the debris particles, surface condition modification of the particles before hitting the surface, thus reducing bonding to the cutting surface. In addition, solvent, additive, surfactant or other cryogenic agents can be added to further the cleaning and decontaminating process, altering potential debris to further reduce adhesion.

Also, the cryogenic aerosol process also allows the management of the temperature of the product which helps to protect sensitive materials from the heat and other physical effects generated by the laser cutting process. For example, the cryogenic assisted laser cutting process according to an exemplary embodiment of the present invention allows the laser cutting of low melting temperature materials such as aluminum without the side effect of local melting, generated by the intense heating of the laser beam. The cryogenic assisted laser cutting process also allows the cutting (e.g. partial cutting of scribing or complete cutting of separating substrate) of heat sensitive semiconducting wafers without the side effect of heat damage.

The current practice of semiconductor industry is to fabricate a plurality of dies into a semiconductor wafer, and then to singulate the wafer into individual dies. The singulation process can be performed by sawing, or by scribing and breaking. The scribing process can include a diamond scriber, a partial saw, groove etch, or a laser beam, and the breaking process can include the pressing the wafer locally by a roller over the wafer to break the semiconductor wafer up into chips.

During the scribe process, debris are generated which needs to be removed for optimal device performance. Diamond scribe or partial saw typically scatter debris around the scribe area, but laser scribe can fuse the debris to the substrate due the high temperature generated by the laser ablation process. In laser scribe, a laser beam is projected on a wafer for a specified time and a specified power to obtain a partial cut through the wafer. The laser is typical a neodymium laser, a Nd:YAG laser or a CO₂ laser. Laser separation is advantageous with ease of cutting hard materials, high throughputs, narrow kerfs of 15-70 um, and no cutting tips to wear.

In an embodiment, the debris is generated after a scribing process of a substrate. In one aspect, the scribing process includes the formation of grooves on a substrate, such as a diamond scribing process, a partial saw process, a laser ablation process, or an etch process. In one aspect, the scribing process is performed on scribe streets, which are typically horizontally and vertically extending lines between the dies to facilitate the separation of the individual dies. In one aspect, the scribing process is a precursor for the die singulating process, such as breaking or complete sawing, to separate the wafer into individual dies. In one aspect, the cleaning process is applied to a substrate for semiconductor processing, such as a wafer, a LCD, a glass or quartz plate, and preferably to a semiconductor substrate such as a silicon wafer.

In an exemplary embodiment, the present invention discloses a cryogenic aerosol cleaning process to reduce thermal damage due to laser irradiation, for example, protecting the high sensitive devices due to the laser high heating, or removing the fused debris on the wafer surface. Excessive heating of the substrate can reduce device performance, reliability and device failure, for example, fused debris can reduce yield if remained on sensitive device areas.

The cryogenic aerosol cleaning according to the present invention can effectively prevent and remove the debris scattered or fused on the wafer surface during the scribing or scoring operation, thus eliminating yield losses due to such damage.

The cryogenic cleaning can provide high efficiency in removing debris, especially in combination with ultrasonic or megasonic agitator assembly, and especially after laser scribing, since high temperature debris produced during scribing can fall on nearby devices and can be fused onto the surface. The cryogenic operation according to the present invention can also prevent the scattering debris from being fused to the wafer surface by providing a temperature shock causing rapid shrinkage to loosen the particles to be removed by the solid gas aerosol, a cold temperature environment causing a mismatch in the thermal coefficient of expansion of the particles and the substrate, or a cold energy source to the debris for cooling before fusing.

The cryogenic or inert gas nozzles preferably point to the area around the laser to prevent or reduce debris redeposition. There can be a plurality of gas or cryogenic nozzles, arranged in multiple zones of debris management and cleaning, around, in front or behind the laser.

The cryogenic nozzles can be arranged around the laser beam into multiple zones. The zones in the immediate vicinity of the laser beam can be low power (e.g., low flow, widely separate nozzles) for redeposition management without affecting the laser cut. The outer zones can be high power for better cleaning, and the outermost zones can be lower power again for debris removal and prevention of debris redeposition. The zones might be skipped (e.g., no low power near the laser beam), or repeated (e.g., cyclic of low/high power nozzles) for maximizing debris management power.

The cryogenic cleaning nozzles can be arranged in front or behind the laser beam, in single, multiple zones or repeated zones of varying powers as above. The cryogenic cleaning nozzles preferably follow the laser beam to clean the debris generated by the laser cut. There can be a plurality of cryogenic cleaning zones or nozzles, either arranged in parallel to cover a wider width, in series for increasing cleaning power, or in a matrix for both width and power improvement. In general, the direction of the laser beam determines the direction of the scribe mark, which in turn determines the direction of the cut on the substrate. The laser beam preferably makes a vertical angle to the substrate to ensure the scribe mark is perpendicular which will provide a vertical cut. In some aspects, the direction of the laser beam can be any angles for an angle cut of the substrate.

The direction of the cryogenic nozzles is preferably making an angle to the substrate. The nozzles preferably blow cryogenic fluid toward the laser beam and toward the uncut portion of the substrate. That way the debris is continuing to be pushed away from the cleaning nozzles. The nozzles can be blown directly toward the laser beam in the direction of the cut, or be blown sideway making an angle with the laser cut.

The plurality of nozzles can all have the same direction for increase the cleaning power. The nozzles can have different direction for optimizing the cleaning power. For example, a more acute angle with the substrate can have less impact but less turbulence or redeposition. A high angle, e.g., increasing the angle to about 45 degrees, with the substrate can have more cleaning power due to high momentum transfer, but could generate turbulence and redeposition. Multiple angles can be employed: high angles for cleaning power and low angles for clean up after.

Sideway direction can clean the debris at one side of the cut, thus three directions of nozzles can be employed: one straight to clean the cut bottom, one left sideways to clean the left bank of the cut, and a right sideways to clean the right bank of the cut.

The cryogenic assisted laser beam assembly preferably comprises an integrated housing for aligning the laser beam with the cryogenic beam. The integrated housing comprises at least a passage for the cryogenic fluid, and at least a passage for the laser beam. The passage for the laser beam preferably allows light to pass through, such as a hollow section or transparent material, or lenses assembly for guiding or focusing the laser beam. The passage for the cryogenic fluid (liquid, gas, or liquid/gas mixture) preferably allows the cryogenic fluid to pass through, such as an inlet/outlet passage, an adapted section for accommodating a cryogenic delivery assembly, such as a cryogenic delivery line and/or a cryogenic nozzle. The assembly is preferably enclosed in an enclosure having an exhaust to remove contaminants, scattered debris, the generated particles, and the cleaning by-products.

In one aspect, the present invention provides an environmental control to improve the efficiency of the cryogenic cleaning mechanism. In an exemplary, the integrated housing is designed to provide a high thermal gradient, allowing a low temperature at the cryogenic fluid and a room temperature at the environment ambient. The interated housing provides condensation control on the delivery line and nozzle, such as by isolating the cold area of the delivery line and nozzles, which can be a vacuum isolation, insulation, vacuum insulation, or a gas purge.

In order to prevent condensation, and particulates from interfering with the cryogenic cleaning action, the cold area of the cryogenic nozzle and its delivery line needs to be isolated from the moisture in the environment. For example, the nozzle and delivery line can be located inside a housing made of poor thermal conductivity, or insulated with a layer of poor thermal conductivity. Such material should be capable of increase the thermal gradient between the low cryogenic temperature and the environment.

In an embodiment, the integrated housing of the nozzles and the laser beam can be made of low thermal conductivity material. The low thermal conductivity prevents the cold temperature of the cryogenic fluid from easily conducting to the housing outside surface, thus preventing condensation of the moisture from the environment, which causes freezing problems. The integrated housing can also be insulated with a low thermal conduction material for preventing the ambient from getting the low temperature of the cryogenic fluid. The integrated housing can also be provided with a partial vacuum insulation section.

The low thermal conductivity material can be plastic, polypropylene, polyethylene, polycarbonate, polysulfone, polystyrene, polyurethane, Polysulphide, polyether, polyester, Propylene, Polychloroprene, Chlorosulfonated Polyethylene, Chlorinated Polyethylene, Polyacrylate, Polysulfide, Polyacrylate, butyl, hypalon, Ultem, Radel, Acetal, Acetate, Cast Acrylic, Polystyrene, Apet, Cpet, Kynar, Acrylic, Nomex, Tectron, Vespel, Nitrile, Isoprene, Butadiene Styrene, Butadiene, Ethylene, Epichlorohydrin, Fluorosilicone, Tetrafluoroethylene/Propylene, Fluoroelastomer-Dipolymer, Fluoroelastomer-Terpolymer, Perfluoroelastomer, phenolics, Viton, Neoprene, Delran, rubbers, elastomers, silicone, nylon, teflon, Kapton, polyimide material, Vinyl Nitrile, PVC, PTFE, FEP, PFA, PVDF, ETEE, ECTFE, PCTFE, PEEK, EPDM, SBR, HNBR, ECO, NBR, TFE/P, CPE, ABS.

An active heating for the outside of the integrated housing can also be provided to further reduce the condensation problem. The active heating is preferably accompanied by a good insulation to prevent affecting the cold temperature of the cryogenic fluid.

In another exemplary, moisture is removed from the enclosure to prevent condensation. Good sealing of the enclosure, partial vacuum or pump/purge cycles can be established inside the enclosure to reduce the moisture. Moisture gettering materials can also be put inside the enclosure to reduce the moisture. Alternatively, low humidity gas or humidity-free gas can be provided in the enclosure, especially around the integrated housing, in the vicinity of the cryogenic beam, in the substrate, in the vicinity of the laser beam, in the enclosure, or any combination thereof to purge the surface of any possible condensation. This purge can prevent secondary condensation problem.

Example of low moisture purge gas can be low moisture nitrogen, air, any inert gases such as helium or argon, or any gases. The purge prevents any kind of secondary icing to develop from moisture in the air, which can be sucked into the process chamber and could freeze up on the wafer, in the process area, or on the nozzle. By adding a low moisture nitrogen purge around and inside the cold area of the nozzle and delivery line, moisture can be replaced, and freeze particles can be avoided.

Reactive process gases, such as SF₆, can be introduced into the process zone to combine with the laser ablated materials, for example silicon for a silicon substrate, to form gas phase by-products, such as SiF₆. This can reduce the solid debris needed removal, resulting in smoother laser scribe or cut.

In another exemplary, flow dynamic enclosure is provided to carry the particles to the exhaust, preventing redeposition. The purge gas can effectively provide an aerodynamic flow or a laminar flow to ensure the exhaust of particles and by-products. The process chamber can be computer modeled to ensure optimization, such as avoiding turbulence, and back flow. The modeling could also account for rapid gas expansion due to the phase shift of the solid cryogenic aerosol, with CO₂ can be provided as carrier gas and debris flow control to effectively exhaust all by-products.

In one aspect, the present invention provides a laser control to improve the performance of the laser scribing mechanism. Additional cooling cryogenic nozzles can be supplied in the vicinity of the laser beam. The additional cryogenic nozzles are preferably low power (than the cleaning nozzles) for debris prevention, reduction, for redeposition control and optional for cleaning during the laser cut. The supplying of a cryogenic zone surrounding the laser beam can reduce adhesion of melted particles redeposited onto the substrate, plus preventing excess temperature of the substrate.

In an embodiment, the cryogenic process can cool instantly the high temperature debris produced by laser scribing, thus adding to the removing power of momentum transfer in knocking the debris out of the wafer surface. The cryogenic operation can effectively reduce the adhesion of the fused debris by the cold temperature management, thus improving the cleaning capability of the cleaning process. With the wafer scribing incorporating a cryogenic cleaning process, a wafer can be reliably scribed with high yield, for various surface conditions, wafer thickness, fragility and thermal sensitivity of the devices.

The cryogenic cooling nozzles preferably surround the laser beam to provide an environmental control of the laser beam. There can be a plurality of cryogenic cooling nozzles, either arranged in parallel, in series or in a matrix to cover a wider width. The power of the cooling cryogenic nozzles can be optimized for cooling, for cleaning, or both. Similar to the cleaning nozzles, the cooling nozzles can provide different directions and angles for optimization purposes.

In one aspect, the present invention provides a high frequency agitator to improve the performance of the cryogenic cleaning mechanism. The cryogenic fluid can be pulsated by ultrasonic or megasonic agitators on the nozzle or on the fluid delivery line before the nozzle. The pulsation of the fluid can be transferred to the ice particles, and thus providing a pulsating action on the cryogenic aerosol cleaning action. The mechanical agitation can also be applied to the substrate surface or the cryogenic liquid. The agitation may include a cleaning process and liquid-based cleaning compositions to dislodge particles. Megasonic cleaning systems, which operate at a frequency over twenty times higher than ultrasonic, can safely and effectively remove particles from materials without the negative side effects associated with ultrasonic cleaning.

Ultrasonic or megasonic assembly typically comprise a piezoelectric transducer coupled to a transmitter. The transducer vibrates when electrically excited, and the transmitter transmits high frequency energy onto the cryogenic fluid or to the substrate, typically using a liquid medium. Particles can be loosened by the agitation of the fluid produced by the ultrasonic or megasonic energy resulting in agitated ice particles post the nozzle. The assembly preferably comprise a probe with large surface area for transmitting a large amount of energy.

The pulsation of the cryogenic fluid can provide high particle removal efficiency with lowest possible damage through cryoaerosol momentum transfer, boundary layer reduction and viscous drag. The cryoaerosol can also exhibit rolling, sliding and bouncing to assist the removal and dislodging of particles.

In an embodiment, the present invention provides an integrated system for cryogenic assist laser scribing and mechanical breaking. The cryogenic assisted laser scribing process is a precursor for the die singulating process, such as breaking or complete sawing, to separate the wafer into individual dies. The debris removal technology through the cryogenic cleaning is integrated into a laser scribe system. The integrated debris removal and laser scribe system can also integrated with a street breaking mechanism to improve yield and reduce damage and breakage.

The substrates employed in the present invention can be semiconductor wafers of a wide range of materials, including silicon, III-V or II-VI materials such as gallium arsenide, sapphire, fragile or delicate wafers such as micro electronic mechanical systems (MEMS), micromechanical devices, III-V or II-VI substrates. The invention is also applicable glass, ceramic and metal wafers or plates in splitting them into chips or forming a grooved pattern on the surface.

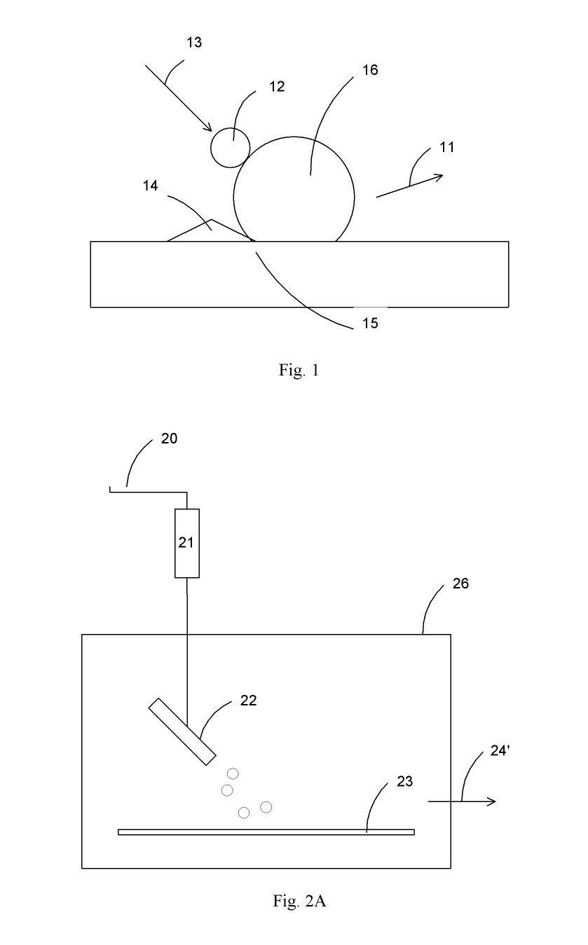

In an exemplary embodiment, the present invention provides a cleaning process that employs a cryogenic aerosol spray, such as a liquid carbon dioxide, argon or nitrogen jet spray, as shown in FIG. 1. Generally, aerosol cleaning is a process of thermophoresis, using colliding cryogenic particles at high velocity against the surface to be cleaned. Liquid carbon dioxide is also a strong solvent for hydrocarbon lubricants, thus can be effective in dissolving hydrocarbon contaminants. In a cryogenic aerosol process, pressurized gaseous carbon dioxide can be provided to a nozzle, where it is expanded. The expansion reduces the pressure of the carbon dioxide to atmospheric pressure, generating solid carbon dioxide particles 12 in the form of dry ice snow striking the contaminated surface to clean. The impact force 13 to the particle 16 can create a drag force 11 to dislodge the particle. The carbon dioxide can also form a soft material, e.g., liquid CO₂ 14 to flow over or under the surface, creating a solvent force 15 to remove the particles without leaving a residue. A filter can be incorporated to ensure high purity carbon dioxide. The cryogenic spray can be pulsated to further facilitate the removal of particles.

Aerosol can also be produced from other gases, liquids or gas/liquid mixtures. When generating aerosol from gas agents, an optional heat exchanger might be used. For cryogenic liquid or gas/liquid aerosol, heat exchanger might not be necessary, thus it is more convenient or less expensive to produce aerosol from cryogenic liquid or gas/liquid.

Effective materials for aerosol include carbon dioxide, argon and nitrogen. For example, solid argon particle-containing aerosol or a mixture of argon/nitrogen aerosol can be used. When generating aerosol from gas, a heat exchanger can be used to cool the gas to near its liquefaction or solidification point. Typically, cryogenic agent has a temperature about −190 F to −300 F and a pressure about 20 psig to 900 psig, preferably greater than 300 psig. Other chemicals, such as helium, neon, krypton, xenon, inert hydrocarbons and mixtures thereof may also be used as cryogen. The cryogenic aerosol supply can also include a supercritical fluid such as supercritical fluid carbon dioxide. Additives or surfactants can also be added.

In an embodiment, the cryogenic aerosol cleaning employs carbon dioxide, argon or argon/nitrogen mixture, and with optional nitrogen carrier gas. The process can be performed at any pressure, but preferably at atmospheric or lower pressure. The cryogenic nozzle can run at a pressure below 900 psi, and preferably higher than 300 psi. The wafer temperature is preferably kept at a low temperature, e.g. lower than 200C for protecting sensitive device. Room temperature environment is also desirable for simplicity setup. The nozzle can run in fixed or vibrational (e.g. pulsed, pulsating, rotating) mode, with pulsation ranging from 0 to 1000 rpm, and 20 to 500 rpm preferred. The cryogenic spray can run in continuous or pulsed mode, with pulsing frequency ranging from sub Hz to thousand of MHz, depending on the applications. Further, megasonic level such as pulsation coupling between between piezo to mechanical can be applied with various multiple different designs.

The cryogenic aerosol can include a nitrogen carrier gas to form an aerosol of substantially solid carbon dioxide or argon particles in a nitrogen carrier gas. The ratio of the nitrogen carrier gas is typically less than 90%. Nitrogen flow rates of up to 1000 slpm may be used. The cryogenic agent or carrier gas can be provided in a typical industrial gas cylinder for high purity, or from a liquid storage tank or a gas pipeline. A metering device such as a mass flow controller can be used. A manifold can be employed for mixing with a carrier gas.

The cryogenic aerosol is preferably directed at an inclined angle (e.g. less than 70 degree, and preferably about 45 degree) toward the scribed surface. The cryogenic aerosol jet is typically at a vertical distance of about 0.1 mm to several inches above the scribed surface. The cryogenic aerosol is expanded through a nozzle, such as circular or slit nozzles. Generally, circular nozzles are employed for localized cleaning, and slit nozzles for broad cleaning. The expansion nozzle can have adjustable diameter orifice. The nozzle configurations can utilize different sizes or patterns to provide different spray patterns and different size ranges. The nozzle is preferably circular with a diameter of between 0.001 to 0.05 inch. A plurality of nozzles can be spaced-apart to provide a two-dimensional scanning.

In an embodiment, the present invention comprises a laser and a cryogenic aerosol nozzle delivering cryogenic aerosol spray. The operations and configurations of the laser and the cryogenic nozzle are designed to optimize the laser cutting process. For example, the cryogenic nozzle and the laser beam can be parallel or can focus to a point, such as a point on the cutting surface. The cryogenic aerosol nozzle can point toward the vicinity of the cutting area where the laser beam hits the cutting surface. The nozzle can point at the laser beam, toward the area where the laser is cutting to delivery cryogenic snow to the heated area of the cutting laser beam. The nozzle can point ahead, toward the area where the laser is going to cut for cooling the area before being cut by the laser. The nozzle can point behind, toward the area where the laser already made the cut for an effective cleaning process. The cryogenic aerosol nozzle can also be parallel to the laser beam, either pointing to the same cutting area, e.g. being concentric around the laser, or leading or lagging the laser beam.

Alternatively, the correlation between the laser beam and the cryogenic beam can be optimized by process control. The laser beam and the cryogenic beam can be continuous or pulsed, delivering power continuously or intermittently to the cutting surface. Any combinations of the laser beam and the cryogenic beam can be used. The pulsing of these two beams can also be non-overlapping, completely overlapping, or partially overlapping. The cryogenic beam can be delivered at the same time, before or after the laser beam.

Further, the cryogenic nozzle can provide a uniform or non-uniform beam of cryogenic aerosol. The profile of the cryogenic aerosol beam can be optimized to improve the cleaning or cooling effects. For example, the cryogenic spray can focus on the area around the laser beam, leaving the laser beam uncooled. The spray can be straightly linear or can be curving around the laser beam. A donut shape cryogenic beam can maximize the laser power by not cooling the laser beam, and providing maximum cooling in the laser vicinity. A high concentration of cryogenic spray in the center and gradually decrease radially can provide effective cleaning, since scattered debris might be concentrated in the vicinity of the laser cut.

In an embodiment, the cryogenic areosol beam can be a focus beam or a spread beam. The cryogenic beam can be as wide as 100 mm, and preferably about 10 mm, since for cooling, the beam range can depend on the substrate material to be cut, and also depending on the sensitivity to heat damage, and for cleaning, depending on the substrate material to be cut, laser debris can scatter about 0.005-100 mm wide.

In another embodiment, the present invention comprises a laser, a cryogenic aerosol nozzle and an exhaust mechanism. The exhaust mechanism removes the scattered debris, the generated particles, and the cleaning by-products. The exhaust mechanism can include means for removing the cleaned and any undesired materials from the cleaning process. This exhaust, including the cleaning medium and the contaminated particles and undesired material, can be removed by exhausting through an exit port, connected to an exhaust pump or a vacuum pump. A purge gas can also be introduced for removing any residues within the process area.

In an embodiment, a cryogenic aerosol spray system having a nozzle is provided in an enclosure. The spray system generates e.g. carbon dioxide snow comprising solid aerosol particles and gas, directed onto the surface of the scribed wafer. The spray includes discrete, substantially frozen, cleaning particles, which can vaporize after impingement on the solid surface of the wafer.

The enclosure can be provided for maintaining a controlled environment during the cleaning process. A purge gas can also be introduced for removing any residues within the enclosure. The cryogenic spray nozzle assembly further includes means for imparting cyclic motion in the spray nozzle so that the cleaning spray is moved bidirectionally relative to the predetermined path at a predetermined amplitude and frequency.

The spray system also includes submicron filters and pressure reduction devices to control the parameters of the cleaning process. The system can include a housing to hold the scribed wafer, and to accommodate the nozzle. The nozzle can include means for supplying a cleaning media. The cleaning media can include a separate supply of carbon dioxide, argon or nitrogen gas and manifold for mixing the cleaning and carrier gases.

The cleaning by-products can be exhausted. The housing can include means for removing the cleaned and any undesired materials from the cleaning process. This exhaust, including the cleaning medium and the contaminated particles and undesired material, can be removed by exhausting through an exit port, connected to an exhaust pump or a vacuum pump. A purge gas can be introduced for removing any residues in the process chamber.

The housing can include temperature control to allow the system to operate at ambient, above ambient, or below ambient temperature. The scribed wafer can be heated to a desired temperature by a heater before cleaning. The housing can include pressure control and flow control sensors and mechanisms, such as exhaust or pumping mechanism to allow the system to operate in vacuum, atmospheric or above atmospheric conditions. The housing can include flush gas for sweeping the interior of the system. These heaters preferably impart surface temperatures to the article that enhance cleaning, prevent re-contamination and remove static electricity. In alternative embodiments, the pre and post heaters are supplemented with, or replaced by, a heated vacuum chuck, with the heated vacuum chuck providing heat to the article to be cleaned, etc.

The nozzle and the laser beam can move along a cut line. The localization of the cryogenic and the laser beam provides good cleaning and cooling power for cleaned laser cutting. The system can include movable assembly to controllably move the substrate surface for surface cleaning. The movable assembly can include a table movably mounted on a linear track or a circular track for movement under the projected spray of the nozzle. The moving assembly can includes a stage movable at least in one direction, and means for holding a substrate on the stage with a source of a laser beam is located above the substrate. The stage is moved with respect to the laser beam to form grooves or to cut on the substrate. In one aspect, a cryogenic nozzle is positioned to provide a cryogenic aerosol to the substrate to remove the debris formed by the laser. In other aspect, the substrate is removed from the cutting apparatus after the cutting operation, and moved to a cleaning station to be clean with a cryogenic aerosol. The substrate movement can be linearly, rotating, or translate in a zigzag pattern, to achieve uniform exposure of the surface to the cleaning aerosol. A substrate handling robot can be employed to position the substrate for cleaning operation, and to remove the substrate after the cleaning operation.

The system can include movable assembly to controllably move the wafer surface for surface cleaning. The movable assembly can include a table movably mounted on a linear track or a circular track for movement under the projected spray of the nozzle. The moving assembly can includes a stage movable at least in one direction, and means for holding a wafer on the stage with a source of a laser beam is located above the wafer. The stage is moved with respect to the laser beam to form grooves on the wafer. In one aspect, a cryogenic nozzle is positioned to provide a cryogenic aerosol to the wafer to remove the debris formed by the laser. In other aspect, the wafer is removed from the scribing apparatus after the scribing operation, and moved to a cleaning station to be clean with a cryogenic aerosol. The substrate movement can be linearly, rotating, or translate in a zigzag pattern, to achieve uniform exposure of the surface to the cleaning aerosol. A wafer handling robot can be employed to position the wafer for cleaning operation, and to remove the wafer after the cleaning operation.

The system can include automation control, such as computer operation for the substrate holder, such as motor with gears and belts, and guide track. The movement of the substrate holder can be linear or rotational. Continuous spray or intermittent spray can be employed. Pulsed cryogenic spray can also be used. The aerosol spray time can usually range from a few seconds to a few hours, typically between 10 seconds to 5 minutes.

The system can include instrumentation to monitor the operating condition, such as pressure, temperature and flow sensors, cooling heat exchanger, the vacuum or vent system, an inert flush gas system and actuation control.

The present invention cryogenic assisted laser cutting can be applied for cleaned laser cutting various materials such as metal (e.g. steel, aluminum), semiconductor, or glass. In an embodiment, the present invention can be for surface cleaning during or after a laser scribing of a substrate.

The invention includes also designs of multiple laser/multiple debris management devices on one platform. e.g. for parallel processing of multiple locations.

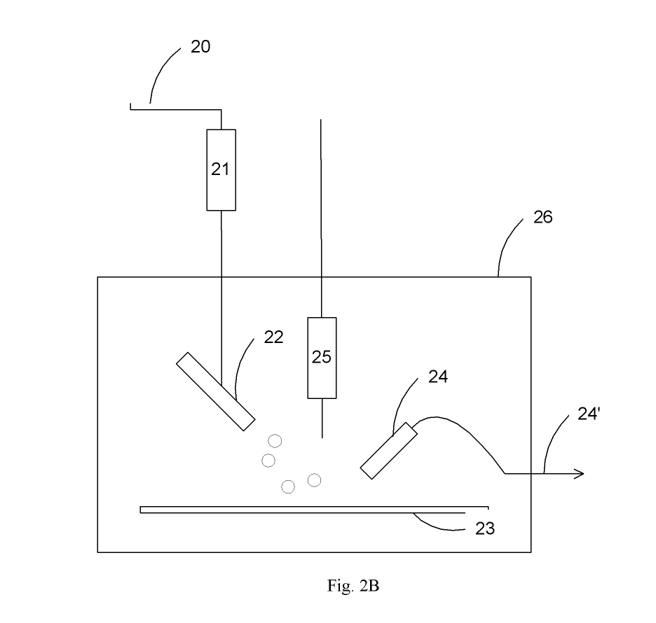

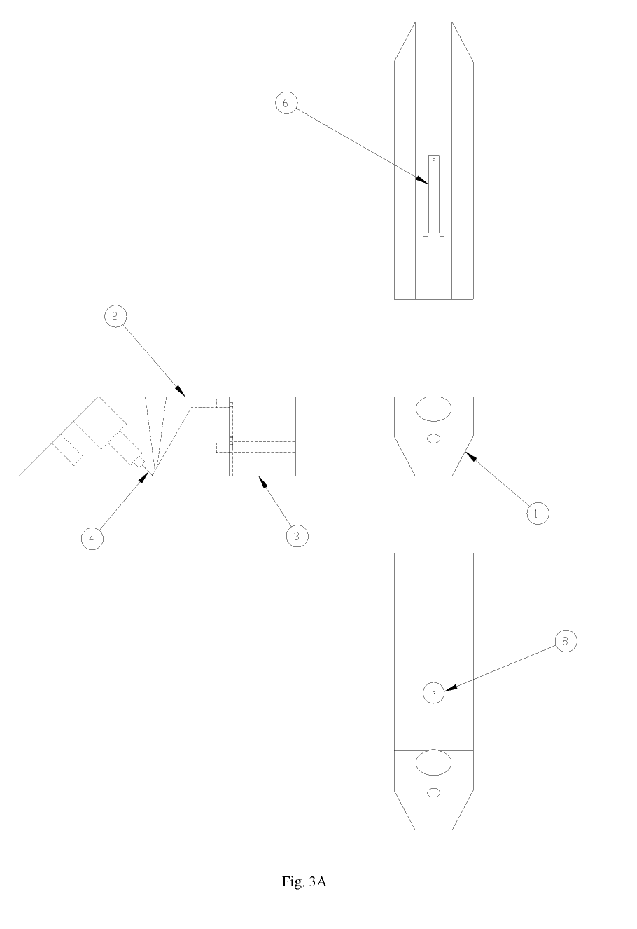

FIG. 2A is a diagram generally illustrating a cryogenic aerosol cleaning system. FIG. 2B is a diagram generally illustrating a cryogenic assisted laser cutting according to the present invention. In this configuration, the cryogenic nozzle 22, the laser beam 25 and the exhaust port 24 are all focused on the cutting point at the substrate surface 23. Cryogenic aerosol equipment includes a source of gas or liquid 20 (e.g. carbon dioxide, argon or argon/nitrogen mixture), and other assembly 21 such as precooling/pressurizing equipment, impurity traps, insulated transfer pipes, and a spray nozzle head for producing aerosol. Precooled gas/liquid at high pressure is expanded in the spray nozzle head to provide solid particles to the scribed substrate, held by a substrate holder. The system can be enclosed in an enclosure 24 with additional exhaust 24′. Optional temperature control, such as a heat lamp, can be provided.

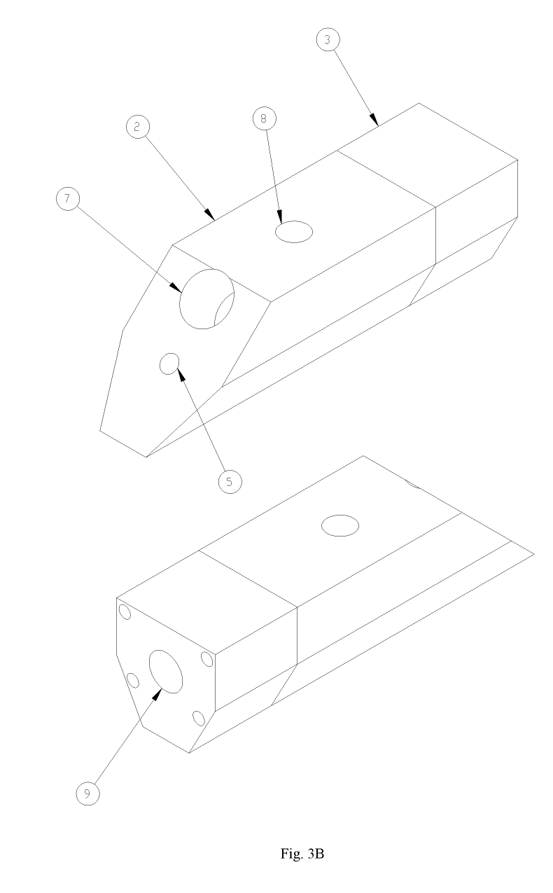

An exemplary integrated housing assembly for laser and cryogenic beam according to the present invention is shown in FIG. 3, which is preferably enclosed inside a cryogenic chamber 1. The assembly comprises two parts: a chamber main body 2 and a vacuum capturing chamber 3. The chamber main body 2 houses the cryogenic nozzle assembly 4. It also has an attachment port 5 to securely attach the cryogenic chamber 1 to a platform or tool system. The chamber main body 2 also includes vacuum opening 6 to collect contaminants and residues generated from the scribing process. Additionally, the chamber main body 2 includes cryogenic supply port 7 feeding cryogenic media to nozzle assembly 4. The chamber main body 2 also includes a thru hole 8 for the laser beam, which can take a form of cylindrical thru hole or as in the preferred embodiment of this invention, a conical shape thru hole. The vacuum capturing chamber 3 includes vacuum port 9 which is used to transfer the collected contaminants and residues generated from the laser cutting process thru a vacuum pumping system away from the processing area. To prevent condensation, the housing assembly can be insulated. For examples, the housing can be made of low thermal conductivity material, or surrounded with low thermal conductivity material. The cryogenic nozzle is perferably made of metal with low orifice for high pressure flow, but the housing is preferably made of low thermal conductivity for prevent condensation at the outer surface. Low humidity environment can also be used, such as moisture getting mechanism, vacuum chamber configuration, low moisture purge gas system, etc.

The present invention cryogenic assisted laser cutting process can be employed in various other applications beside laser, such as plasma or mechanical cutting. The present invention cryogenic assisted laser cutting process can be expanded to also cover any cutting process with high generated local temperature. For example, the cutting processes can include laser cutting, plasma cutting, or mechanical-cutting style. The cutting process can also be applied to other materials and surfaces such as metals, polymers, ceramics, as well as semiconductor articles.

The present invention cryogenic assisted laser cutting process can be employed in various other applications beside cutting. Thus the present invention cryogenic assisted process can be vastly expanded to also cover any process with high generated local temperature, which can benefit from the low temperature or the cleaning power of the cryogenic spray.

In an embodiment, the cleaning process is performed in series with the scribing process. The cleaning process can be performed concurrently with the scribing process. The cleaning process can also follow immediately the scribing process, creating a pair of beam upon the wafer, one beam for the laser scribing process and one beam for the cryogenic aerosol cleaning. The cleaning and the scribing processes can be performed separately, e.g., the cleaning can be performed before (pre-cleaning)/after the completion of the scribing process for a street, or a whole wafer. For example, the cryogenic aerosol cleaning nozzle can point directly at the site of the laser scribing beam, or the nozzle can deliver cryogenic aerosol at the point of the ablation. The cryogenic aerosol cleaning nozzle can deliver cleaning agents at the vicinity of the laser beam, immediately before, immediately after, or covering the laser beam. The cleaning process can be performed in the same process chamber, or in separate process chamber.

In an embodiment, the debris cleaning is localized and focused on the scribed mark areas. The debris generated from the scribing process typically scatters in the vicinity of the scribe streets, the cleaning process can focus on the areas surrounding the scribe marks, e.g. executing a slower sweep time for a better cleaning operation in the vicinity of the scribe marks, and executing a faster sweep time for a higher throughput outside the scribe mark areas. A typical scattering patterns from a laser ablation can spread outward about 10 mm, thus for larger dies, the focusing of the cleaning nozzle on the scribe marks can improve the cleaning throughput. Alternatively, the cleaning can performed throughout the wafer surface, especially for small dies.

In an embodiment, the cleaning process of cryogenic aerosol is performed for cleaning debris after a laser ablation scribing. In one aspect, the cryogenic aerosol can act as an environment management and temperature management to reduce the adhesion of the debris, thus allowing faster and easier cleaning. For example, the cryogenic aerosol process creates a cold environment where the debris is cooled before hitting the wafer surface, thus preventing the particles generated from the ablation to physical bond to the surface. The cold temperature effect of the cryogenic aerosol can reduce the temperature of the debris particles and also the vicinity of the laser ablation area to protect the devices on the wafer, e.g. temperature sensitive devices or materials such as low-k layers. In addition, other chemicals such as solvents can be introduced to potentially alter the debris to reduce the adhesion or ease of debris removal. The cryoaerosol from the physical bombardment sweeps the particles away to prevent the debris from lying on top of the surface, effecting device performance and yield.

In an embodiment, the cryogenic process can cool instantly the high temperature debris produced by laser scribing, thus adding to the removing power of momentum transfer in knocking the debris out of the wafer surface. The cryogenic operation can effectively reduce the adhesion of the fused debris by the cold temperature management, thus improving the cleaning capability of the cleaning process. With the wafer scribing incorporating a cryogenic cleaning process, a wafer can be reliably scribed with high yield, for various surface conditions, wafer thickness, fragility and thermal sensitivity of the devices.

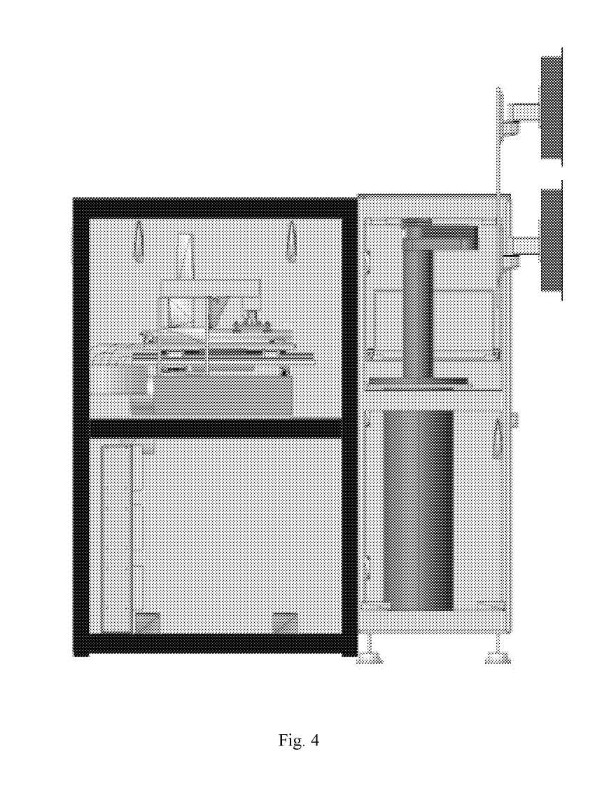

The present invention further provides optional equipment such as an automation system with X-Y movement and rotation, robotic for moving wafers, scribe station and singulating station for separating the individual dies. FIG. 4 shows an exemplary system incorporating cryogenic assist laser scribe mechanism, including a robot transfer assembly, a cryogenic-assisted laser scribe assembly and equipment section.

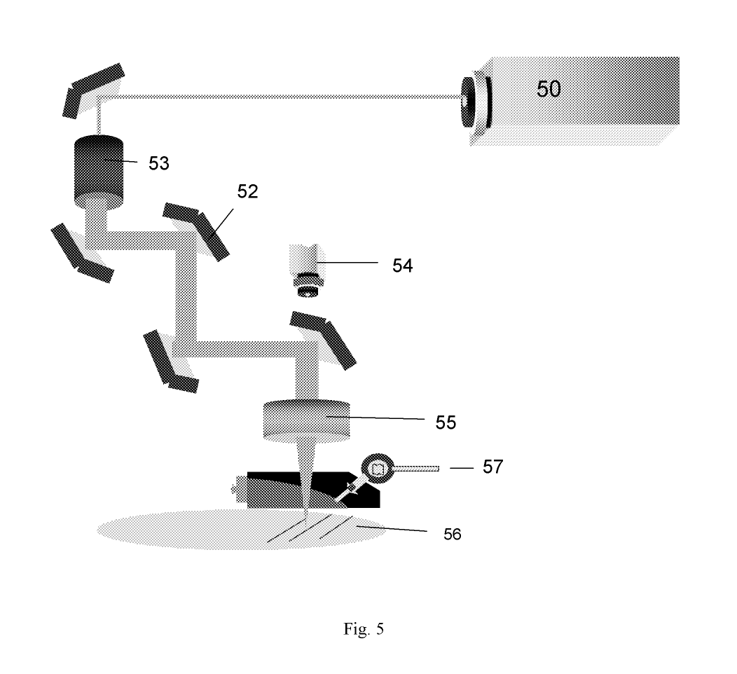

FIG. 5 shows an exemplary laser assembly, comprising a tuned laser 50 going through a series of mirrors 52, an expander/collimator 53 and focusing lens 55 before reaching a substrate 56. The system can also comprise a camera 54 for vision detection, and a cryogenic aerosol assembly 57 for cleaning.

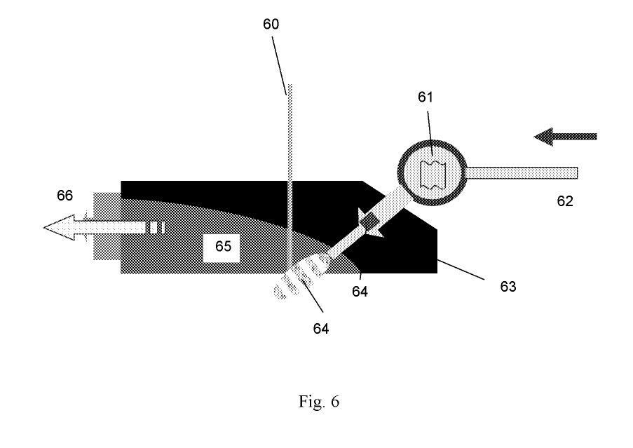

FIG. 6 shows an exemplary cryogenic assist laser scribing assembly, comprising a tuned laser 60 making scribes and/or cuts on a substrate, and a cryogenic aerosol assembly 61 for debris cleaning. The cryogenic aerosol assembly comprises an injection of liquid CO₂ 62 into an integrated housing 63 and environment for cleaning the laser generated debris. The cryogenic aerosol can provide a controlled cool zone 65, for example at 120C or below, with cryogenic ice crystal 64. The environment can be designed for aerodynamic flow of the debris exhaust 66 to prevent turbulence and redeposition of by-products.

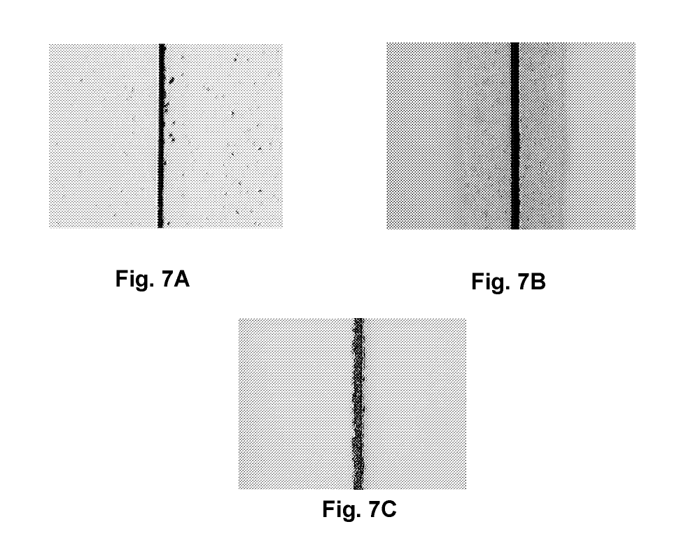

FIG. 7 show a scribed surface after laser scribing. FIG. 7A shows a laser scribed surface without any cryogenic cleaning. In this specific embodiment, the power is set less than 10 W, and preferable from 1 to 5 W. FIG. 7B shows a laser scribed surface with cryogenic cleaning. The sweeping rate of the cryogenic nozzle is set between 10 to 500 mm/sec, and preferably between 50 to 200 mm/sec. FIG. 7C shows a surface with cryogenic assisted laser scribe with the cryogenic assembly well insulated against condensation. The power and the sweeping rate shown are exemplary to the substrate being employed, but in general, the power and the sweeping rate can be set at any value depending on the circumstances, e.g. the power can be higher than 10 W, or the sweeping rate can be lower than 10 mm/sec or higher than 500 mm/sec.

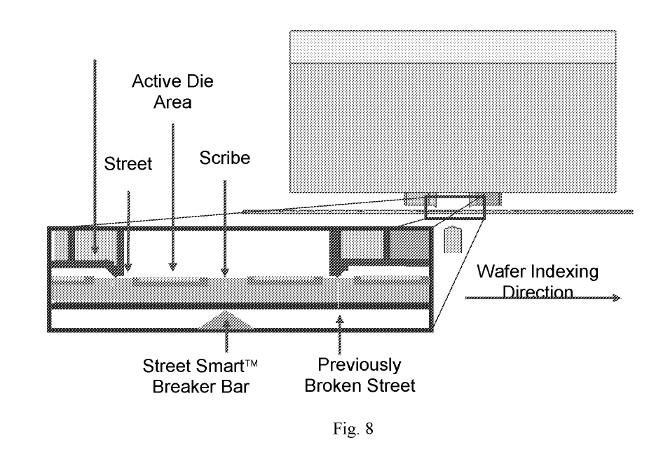

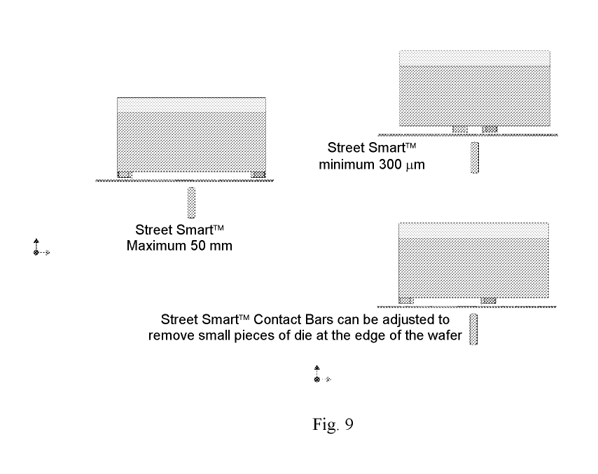

FIG. 8 and FIG. 9 show a street breaking assembly and a street breaking mechanism. Minimum damage to the substrate can be achieved by applying the breaking mechanism to the non-sensitive surface areas of the wafer, such as the wafer streets, to avoid damaging the wafer devices, and then the breaking mechanism applying a force to break the wafer along a scribe line. Alternatively, the force on the breaking mechanism can cleave the wafer, starting from the location where the force is applied, and creating a splitting operation along the scribe line of the wafer. The cleaving operation is similar to the breaking, with the breaking done at an edge and the break is propagating through the wafer. One preferred embodiment comprises a breaker bar to press on a backside of a scribe line, and an anvil mechanism to press on the non-sensitive surface areas of the wafer. By pressing the breaker bar relative to the anvil mechanism, the wafer can be broken or cleaved along the scribe line. An optional base fixture holds the wafers during the breaking operation which may be purged with nitrogen.

To prevent damage to the semiconductor wafer surface, the breaking mechanism contacts the top surface of the semiconductor wafer only in the non-sensitive areas between the dies. Taking advantage of the design of semiconductor wafer processing where multiple dies are fabricated on the same wafer, and therefore there exists non-sensitive, non-active areas on the wafer around the individual dies to facilitate the separation of the dies. The non-sensitive areas around the dies are called streets, since it resembles a street map. Typically, the dies are having the same area and periodically arranged on the wafer.

The apparatus includes a breaking mechanism for applying a force to a scribe line. A force can be applied to the whole scribe line, resulting in a wafer breaking operation, a force can be applied to a segment of the scribe line, resulting in a cleavage operation propagated from where the force is applied, or any combination operation between the breaking mechanism and the cleavage mechanism. The force can be applied to the inside of the wafer, or the force can be applied over the edge of the wafer.

The breaking mechanism preferably comprises a top anvil mechanism and a breaker bar where the breaker bar has a knife-edge which applies a force to the backside of wafer at the scribe line against the anvil mechanism which presses on non-sensitive surface areas on the topside of the wafer.

The top anvil mechanism provides the support or the downward force on the topside of the wafer. The top anvil mechanism of the present invention only applies force on the top surface of the semiconductor wafer in the non-sensitive parts of the wafer, which are the streets. In a preferred embodiment, the top anvil mechanism comprises a plurality of top down bars, preferably two bars, that contact the wafer's topside and an adjustment mechanism that can adjust the gap between the two adjacent bars. This allows for varying die sizes, as is common is the semiconductor manufacturing industry. This whole top anvil mechanism can move up and down, for example, by a vertical slide assembly that is a part of a machine employing the street smart breaking mechanism.

The top down bars are designed to press only the non-sensitive surface areas, preferably on the adjacent scribe lines on opposite sides of the street to be broken. The top down bars are preferably having a minimum surface contact with the wafer, such as a taper edge at the contact end. In one embodiment, the top down bars have a dull knife edge such as a taper round edge to provide a minimum contact surface while not damaging the wafer. To improve alignment, the taper edge is preferably positioned toward the outer side of the top down bar, leaving the dies to be broken or cleaved clear from obstruction. The top down bar is preferably a bar, but can be a pointed cylinder to press on the wafer at a point, or a cross shape surface to press on the wafer at the intersection of the streets.

On a full wafer, the streets are intact, and the top down bars are preferably pressing at the middle of the streets. On a partial wafer where the streets have been broken, the top down bars can press on the inside half of the streets to form the anvil mechanism for the breaker bar.

The breaker bar is preferably a static bar that provides the fulcrum over which the wafer is stressed during the breaking process. A plurality of breaker bars can be used for simultaneously multiple breaking operations. The breaking operation resulted from the applied force resulting from the relative movement of the top anvil mechanism and the breaker bar. The applied force can be an impulse which imparts a shock to the wafer to produce a fracture. The force can be a gradual force which provides a gradually increased stress or strain to the wafer to produce a fracture. The force can be applied to the whole length of the wafer or the wafer segment, resulting in a breaking operation. The force can be applied to an inside portion of the wafer or the wafer segment, resulting in a breaking operation. The force can be applied to an edge portion of the wafer, resulting in a cleavage operation that propagates throughout the length of the scribe line.

The present invention provides an integrated cryogenic assisted laser scribing in combination with a street breaking mechanism for improving singulating efficiency. The integrated system according to the present invention can provide reliability improvement, especially for thin substrates, by minimizing the handling and transportation of the substrates between the scribing station and the breaking station.

The integrated system can comprise a stationary support for handling the substrates. This will minimize the motion of the substrate, and thus improves the reliability of the singulating process, preventing damage to the substrate, especially after the cryogenic assisted laser scribed operation. In this aspect, all movements are provided by the scriber head and the breaker head, with the substrate stationary. The stationary support can have limited movements to accommodate the scriber head and the breaker head. For example, the stationary support can travel linearly or rotationally under the scriber or breakers. The limited movement of the stationary support can simplify the integrated system design without much impact on the reliability of the singulating system.

The integrated system can comprise a movable support for handling and transport the substrates from a scribing station to a breaker station. The movable support can also have limited movements to accommodate the scribing station and the breaking station.

What is claimed is:

1. A method of cryogenic-assist debris management for substrate singulation, comprising:
providing a substrate;
performing at least a substrate singulating process selected from a group of scribing, cutting, and breaking the substrate, the substrate singulating process generating debris;
managing the debris generation by flowing cryogenic aerosol in the vicinity of the substrate singulating process for improving the surfaces of the substrate resulted from the singulating process.

2. A method as in claim 1 wherein flowing cryogenic aerosol provides thermal shock to loosen debris.

3. A method as in claim 1 wherein flowing cryogenic aerosol cools debris or substrate surface to prevent debris fusing with the substrate.

4. A method as in claim 1 wherein further comprising controlling the debris flow to minimize debris redeposition on the substrate surface.

5. A method for cryogenic-assist laser singulation process, comprising:
providing a substrate;
performing at least a substrate laser singulating process selected from a group of laser scribing and laser cutting the substrate, the laser singulating process generating debris;
managing the debris generation with a cryogenic nozzle generating cryogenic aerosol in the vicinity of the laser beam.

6. A method as in claim 5 wherein the cryogenic nozzle prepares the substrate with a low power before laser processing.

7. A method as in claim 5 wherein the cryogenic nozzle cleans the substrate with a high power after the laser processing.

8. A method as in claim 5 wherein the cryogenic nozzle cleans the substrate during the laser processing.

9. A method as in claim 5 wherein there is a plurality of cryogenic nozzles for managing debris repeatably and in a wide area of the laser processing.

10. An apparatus for cryogenic-assist laser singulation process, comprising:
a substrate;
a laser beam for singulating the substrate, the singulating process generating debris;
a cryogenic nozzle generating cryogenic aerosol in the vicinity of the laser beam for debris management.

11. An apparatus as in claim 10 wherein the cryogenic nozzle provides a low power at the intersection of the laser beam and the substrate.

12. An apparatus as in claim 10 wherein the cryogenic nozzle provides a high power in the vicinity of the intersection of the laser beam and the substrate.

13. An apparatus as in claim 10 wherein the cryogenic nozzle provides a low power at outside the vicinity of the intersection of the laser beam and the substrate.

14. An apparatus as in claim 10 further comprising a plurality of cryogenic nozzles arranging in parallel for wide cleaning area outside of the laser beam.

15. An apparatus as in claim 10 further comprising a plurality of cryogenic nozzles arranging in series for repeating the cleaning action at essentially the same point of the laser beam.

16. An apparatus as in claim 10 further comprising introducing reactive gas for reacting with debris and converting into gaseous form for ease of removal.

17. An apparatus for cryogenic-assist singulation process, comprising:
a substrate;
a singulating mechanism for singulating the substrate, the singulating process generating debris;
a cryogenic nozzle generating cryogenic aerosol for debris management, the cryogenic nozzle comprising a housing made of low thermal conductivity material for preventing condensation due to the low temperature of the cryogenic process.

18. An apparatus as in claim 17 further comprising a heater mechanism to provide a heated environment surrounding the cryogenic nozzle.

19. An apparatus as in claim 17 further comprising a heated environment surrounding the cryogenic nozzle.

20. An apparatus as in claim 17 further comprising a moisture gettering mechanism to reduce moisture in the environment surrounding the cryogenic nozzle.

21. An apparatus as in claim 17 further comprising a purging mechanism to reduce moisture in the environment surrounding the cryogenic nozzle.

22. An integrated apparatus for substrate singulation process, comprising:
a substrate support for supporting the substrate;
a cryogenic-assist laser scribing station comprising:
a laser beam for scribing the substrate, the laser scribing process generating debris; and
a cryogenic nozzle generating cryogenic aerosol in the vicinity of the laser beam for debris management;
a substrate breaking station for singulating the substrate into dies; and
a movement mechanism for transferring the substrate between the stations with minimum damage.

23. An apparatus as in claim 22 wherein the substrate support is stationary and the stations moves toward the substrate.

24. An apparatus as in claim 22 wherein the substrate support moves linearly between the stations.

25. An apparatus as in claim 22 wherein the stations are integrated on the same substrate support.
